(19) United States
(12) Patent Application Publication
(10) Pub. No.: US 2021/0375799 A1
(43) Pub. Date: Dec. 2, 2021

(54) LOW-LOSS MILLIMETER WAVE TRANSMISSION LINES ON SILICON SUBSTRATE

(71) Applicant: Mobix Labs, Inc., Irvine, CA (US)

(72) Inventors: Oleksandr Gorbachov, Irvine, CA (US); Lisette L. Zhang, Irvine, CA (US)

(21) Appl. No.: 17/331,227

(22) Filed: May 26, 2021

Related U.S. Application Data
(60) Provisional application No. 63/032,162, filed on May 29, 2020.

(51) Int. Cl. H01L 23/66; H01P 3/00; H01P 3/08

(52) U.S. Cl. CPC H01L 23/66; H01P 3/006; H01L 2223/6672; H01L 2223/6627; H01P 3/081

(57) ABSTRACT

A semiconductor die and a transmission line structure has a first doped semiconductor substrate and a radio frequency transmission line disposed above the first doped semiconductor substrate. A second doped semiconductor segment is defined in the first doped semiconductor substrate and is arranged in a transverse relationship to a transmission line axis, with a depletion region being defined in areas of the first doped semiconductor substrate adjacent thereto that reduces power loss in signals through the transmission line.

### CROSS-REFERENCE TO RELATED APPLICATIONS

This application relates to and claims the benefit of U.S. Provisional Application No. 63/032,162 filed May 29, 2020 and entitled “LOW-LOSS MILLIMETER WAVE TRANSMISSION LINES ON SILICON SUBSTRATE” the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure relates generally to semiconductor devices and radio frequency (RF) integrated circuits, and more particularly to low-loss millimeter wave transmission lines on silicon substrates.

### 2. Related Art

Many different mobile communication technologies or air interfaces are known in the art, with various generations of these technologies being deployed in phases, the latest being the 5G broadband cellular network system. The air interfaces for 5G networks include a frequency band with an operating frequency above 24 GHz, also known as millimeter wave (mmWave). As a general matter, wireless communications systems are comprised of multiple intercommunicating nodes, with each node including at least a baseband system, an RF transceiver that modulates the baseband signal with an RF carrier signal, a front end circuit that amplifies the outgoing transmit signal as well as the incoming receive signal, and to or from single or array antennas. The front end circuit, as well as any other component of the wireless communications node may be implemented as an integrated circuit that is fabricated on a semiconductor die.

These front end integrated circuits may have numerous RF transmission lines interconnecting the various active and passive components, and conventionally, the RF transmission lines that are placed on the silicon substrates are prone to high levels of energy loss. To a large extent, these losses are associated with the free carriers that are inside the silicon substrate. Additionally, the higher the operating frequency, the higher the resulting loss, and with signals in the mmWave-range operating frequencies, the losses can be substantial. The electric and magnetic fields that penetrate into the silicon substrate are understood to excite corresponding high-frequency currents in different directions, thereby resulting in higher signal power loss. Even a small layer of the silicon substrate, e.g., ˜1 μm thick, is understood to strongly influence substrate-related power losses.

There are several known techniques for reducing these signal power losses that are attributable to the silicon substrate. For instance, high resistivity silicon substrates, with resistivities greater than 1 kOhm*cm, may be used for passive circuits. However, such high-resistivity substrates are not used for active circuits because of significant latch-up problems and large variations in current resulting from a wide range of doping levels (from 700 Ohm*cm to 3k Ohm*cm) affecting yield. More typically, the resistivity of bulk substrates that are used for RF frequency applications may be between 1 Ohm*cm and 10 Ohm*cm. Another approach for reducing substrate loss is utilizing porous silicon underneath the RF transmission lines, though this is not understood to be a standard process for high volume production.

The use of a pattern shield with grounded polysilicon strips under inductive elements is also known. This is understood to protect electric field penetration into the silicon substrate, and partially reduce losses. Nevertheless, magnetic field penetration into the silicon substrate still occurs, resulting in associated losses. Moreover, the quality factor (Q-factor) of such inductive elements may be reduced because of the closely positioned conductive polysilicon strips. With mmWave devices, the complete shielding of the silicon substrate from the transmission line with complete metal layers is also known, though some performance characteristics of the transmission line are known to deteriorate.

Still another known approach is the placement of N-wells under the inductive elements. N-wells with large geometric dimensions are needed to cover the entire area under the inductive elements, however, are understood to result in large capacitances, which likewise deteriorates the Q of the inductive element and reduces maximum usable frequencies.

Accordingly, there is a need in the art for improved low-loss transmission line structures implemented on silicon substrates, particularly those that are suitable for signals in the mmWave frequency range.

### BRIEF SUMMARY

The present disclosure is directed to various embodiments of semiconductor integrated circuit transmission line structures for minimizing losses associated with free carriers in the semiconductor/silicon substrate, particularly those carrying radio frequency (RF) signals in the millimeter-wave range. The embodiments contemplate the insertion of narrow N-well strips underneath the transmission lines that are separated by shallow trench isolation (STI) strips, which create a large depletion area in the substrate of high resistivity. Voltage applied to the N-well strips may further expand the depletion area. The disclosed structures may be fabricated with conventional complementary metal oxide semiconductor (CMOS) processes.

According to one embodiment of the disclosure, there may be a semiconductor integrated circuit transmission line structure that includes a first dielectric layer and a first doped semiconductor substrate. Additionally, there may be a transmission line that is disposed on the first dielectric layer. The transmission line may extend along a transmission line axis. There may also be one or more lateral second doped semiconductor strips that are defined in the first doped semiconductor substrate. Each of the lateral second doped semiconductor strips may be connectible to a voltage source. Furthermore, the lateral second doped semiconductor strips may be transverse to the transmission line axis and spaced along the transmission line. The transmission line structure may also include a shallow trench isolation structure that is defined in the first doped semiconductor substrate. The shallow trench isolation structure may also be laterally adjacent to the lateral second doped semiconductor strips.

According to another embodiment of the present disclosure, there may be a semiconductor die with a first doped semiconductor substrate, along with an RF transmission line that may be disposed above the first doped semiconductor substrate and extend along a transmission line axis. The semiconductor die may include a second doped semiconductor segment defined in the first doped semiconductor substrate. The second doped semiconductor segment may be arranged in a transverse relationship to the transmission line axis, with a depletion region being defined in areas of the first doped semiconductor substrate adjacent thereto that reduces power loss in signals through the RF transmission line.

According to another embodiment of the present disclosure, there may be a semiconductor integrated circuit transmission line structure. The structure may include a first doped semiconductor substrate and a transmission line that may extend along a transmission line axis. There may also be one or more sets of second doped semiconductor fills. Each of the second doped semiconductor fills in a given set may be arranged in a spaced relation transverse to the transmission line axis. Each of the sets of the second doped semiconductor fills may be spaced along the transmission line. There may also be a shallow trench isolation structure that is defined in the first doped semiconductor substrate and is laterally adjacent to the lateral second doped semiconductor fills.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIGS. 1A, 1C, and 1B are cross sectional views of semiconductor dies with different transmission line configurations, including a microstrip line, a grounded co-planar wave guide (GPCW) line, and a microstrip line in a flip-chip configuration, respectively;

FIG. 2 is a top plan view of a first embodiment of a transmission line structure according to the present disclosure;

FIG. 3 is a perspective view showing a cross section of the first embodiment of the transmission line structure of FIG. 1;

FIG. 4 is a top plan view of a second embodiment of the transmission line structure according to the present disclosure;

FIG. 5 is a detailed perspective view showing a cross section of the second embodiment of the transmission line structure with equivalent circuit components associated with various parts of the transmission line structure;

FIG. 6 is a top plan view of a third embodiment of the transmission line structure according to the present disclosure;

FIG. 7 is a top plan view of a fourth embodiment of the transmission line structure according to the present disclosure;

FIG. 8 is a perspective view showing a cross section of the fourth embodiment of the transmission line structure of FIG. 7; and

FIG. 9 is a perspective view showing a cross section of a fifth embodiment of the transmission line structure.

### DETAILED DESCRIPTION

This disclosure contemplates various embodiments of RF transmission line structures that minimize energy loss, and semiconductor dies utilizing the same. According to various embodiments, narrow N-well strips are disposed underneath the transmission lines and are separated from each other by dielectric strips that are STI (shallow trench isolation) structures. The N-well strips are envisioned to define a large area of high resistivity in the semiconductor substrate corresponding to a depletion area of the P-N junction, with resultant reduction in power loss through the transmission line. A voltage may be applied to the N-well strips may increase the depletion area, and further reduce loss. The contemplated structures may be adapted to different types of transmission lines and signal frequencies, including millimeter-wave frequencies.

The detailed description set forth below in connection with the appended drawings is intended as a description of the several presently contemplated embodiments of the semiconductor integrated circuit transmission line structure and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second, top and bottom, proximal and distal and the like are used solely to distinguish one from another entity without necessarily requiring or implying any actual such relationship or order between such entities.

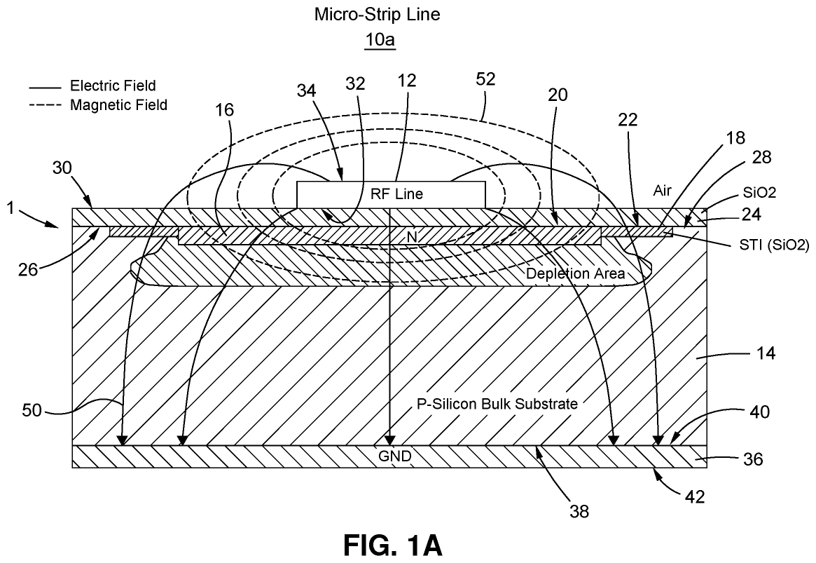

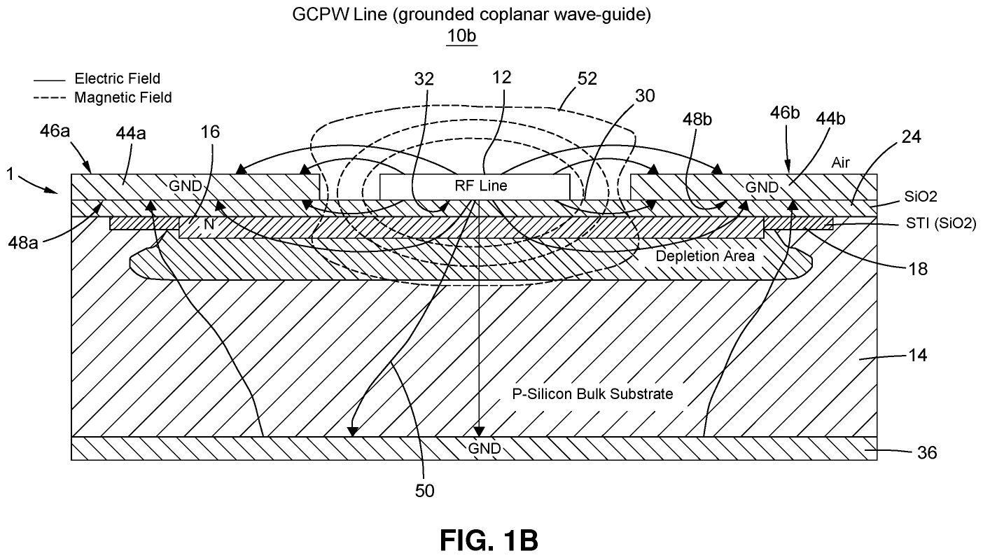

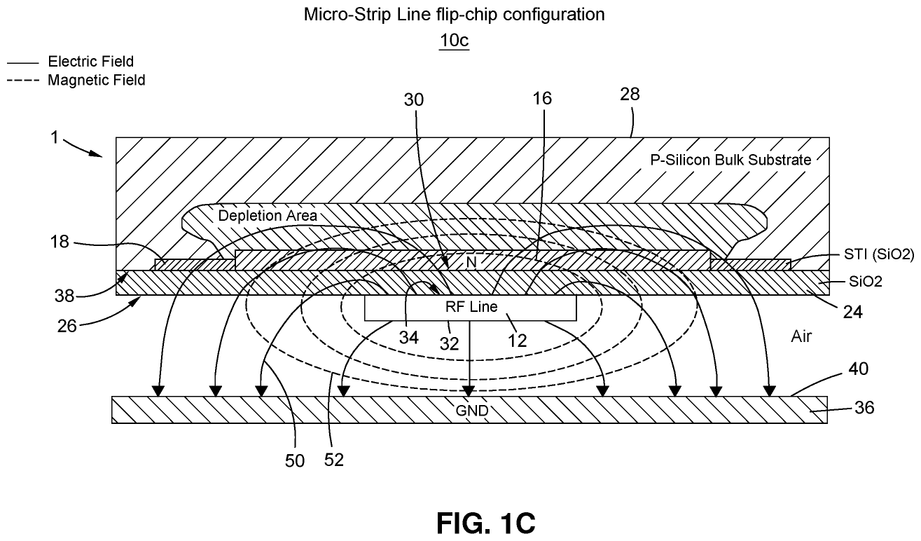

FIGS. 1A, 1C, and 1C illustrate the cross sections of a portion of a semiconductor integrated circuit 1 that may serve as the basis for the transmission line structures of the present disclosure. In particular, FIG. 1A is of a micro-strip line configuration 10a in which an RF transmission line 12 is disposed on a semiconductor (e.g., silicon) bulk substrate 14. According to various embodiments, the semiconductor bulk substrate 14 is a P-type semiconductor, that is, doped with P-type or electron acceptor dopant element such as boron or gallium. Additionally, an N-well 16 may be defined in the semiconductor bulk substrate 14, which is fabricated by a diffusion of N-type semiconductor into a suitable recess formed in the semiconductor bulk substrate 14. A shallow trench isolation (STI) structure 18 comprised of silicon dioxide (SiO₂) may surround the N-well 16.

A top surface 20 of the N-well 16 may be generally co-planar with a top surface 22 of the STI structure 18. The semiconductor integrated circuit 1 may further include an inter-layer (SiO₂) dielectric 24 that is defined by a bottom surface 26 that abuts against the top surface 20 of the N-well 16, the top surface 22 of the STI structure 18, and a top surface 28 of the semiconductor bulk substrate 14. The inter-layer dielectric 24 is also defined by a top surface 30 that is opposite the bottom surface 26, and the RF transmission line 12 is positioned thereon. A bottom surface 32 of the RF transmission line 12 is in an abutting relationship to the top surface 30 of the inter-layer dielectric 24. The RF transmission line 12 is also defined by a top surface 34 that is opposite the bottom surface 32.

Underneath the semiconductor bulk substrate 14, there may be a ground plane 36. The semiconductor bulk substrate 14 is also defined by a bottom surface 38 that is opposite the top surface 28, and the ground plane 36 is similarly defined by a top surface 40 and an opposed button surface 42. The bottom surface 38 of the semiconductor bulk substrate 14 faces and is abutting against the top surface 40 of the ground plane 36.

FIG. 1B illustrates a micro-strip line configuration 109b with a grounded coplanar wave guide. Again, the RF transmission line 12 is disposed on the semiconductor bulk substrate 14 with P-type doping along with the N-well 16 that is surrounded by the STI structure 18. Underneath the semiconductor bulk substrate 14 is the ground plane 36, and on top of the inter-layer dielectric 24 is the RF transmission line 12. The top surface 30 of the inter-layer dielectric 24 faces and is abutting against the bottom surface 32 of the RF transmission line 12.

Also disposed on the inter-layer dielectric 24 are grounded waveguides 44, including a first grounded waveguide 44a spaced apart and to the left of the RF transmission line 12, and a second grounded waveguide 44b spaced apart and to the right of the RF transmission line 12. The first grounded waveguide 44a is defined by a top surface 46a and an opposed button surface 48a that faces and abuts against the top surface 30 of the inter-layer dielectric 24. The second grounded waveguide 44b is similarly defined by a top surface 46b and an opposed bottom surface 48b that faces and abuts against the top surface 30 of the inter-layer dielectric 24. Aside from the specifically referenced surfaces, the other surfaces of the semiconductor bulk substrate 14, the N-well 16, the STI structure 18, the inter-layer dielectric 24, and the ground plane 36 are understood to be the same as micro-strip line configuration 10a discussed above, so they will not be repeated for the sake of brevity.

FIG. 1C illustrates a micro-strip line configuration 10c in a flip-chip arrangement. The orientations of the different parts are understood to be the opposite of the micro-strip line configuration 10a shown in FIG. 1A, and there may be differing RF signal power losses as will be described in further detail below. Nevertheless, the same semiconductor bulk substrate 14 with P-type doping is defined by the top surface 28 and the opposing bottom surface 38. Toward the bottom surface 38 is the N-well 16 that is surrounded by the STI structure 18. Disposed below the N-well 16 and the STI structure 18 is the inter-layer dielectric 24 that is defined by the top surface 30 and the opposed bottom surface 26. The RF transmission line 12, and specifically the top surface 34 thereof, abuts against and faces the bottom surface 26 of the inter-layer dielectric 24. Separated from the inter-layer dielectric 24 and the RF transmission line 12 and positioned below the same is the ground plane 36. The top surface 40 faces and is spaced apart from the bottom surface 26 of the inter-layer dielectric 24 and the bottom surface 32 of the RF transmission line 12.

Regardless of the micro-strip line configuration 10a, 10b, and 10c, when the RF transmission line 12 is carrying an RF signal, electric fields and magnetic fields are understood to be generated thereby. Generally, the E-field (electric field) lines 50 and the H-field (magnetic field) lines 52 are in a transverse plane to the RF wave propagation and are illustrated as such in each of FIGS. 1A, 1B, and 1C. For both electric field lines 50 and magnetic field lines 52, there may be various losses associated with the components of the semiconductor die as such electric and magnetic fields pass through such components to ground (the ground plane 36 in the case of all micro-strip line configurations 10a, 10b, 10c, and additionally the grounded waveguides 44 in the case of the second micro-strip line configuration 10b). The losses include those in the metal of the RF transmission line 12 that carries the signal, those in the SiO₂ inter-layer dielectric 24, and those in the semiconductor bulk substrate 14.

At millimeter wave frequencies, the highly doped, P-type semiconductor bulk substrate 14 is understood to represent the largest contribution to loss. Insertion of an N-type dopant into the semiconductor bulk substrate 14 in accordance with the present disclosure is contemplated to reduce those losses. As described above, various embodiments of the micro-strip line configurations 10 incorporate the N-well 16 oriented in a direction transverse to the RF transmission line 12. In further detail, the junction between the N-well 16 and the P-type semiconductor bulk substrate 14, regardless of the specific configuration 10a, 10b, or 10c, defines a depletion area or region 35 in which free electrons in the N-type semiconductor diffuse into the side of the P-type semiconductor bulk substrate 14, while the holes in the P-type valence band diffuse into the N-type semiconductor valence band. The depletion region 35 is understood to be highly resistive, and the RF signal loss associated with the electric field and the magnetic field may be significantly reduced.

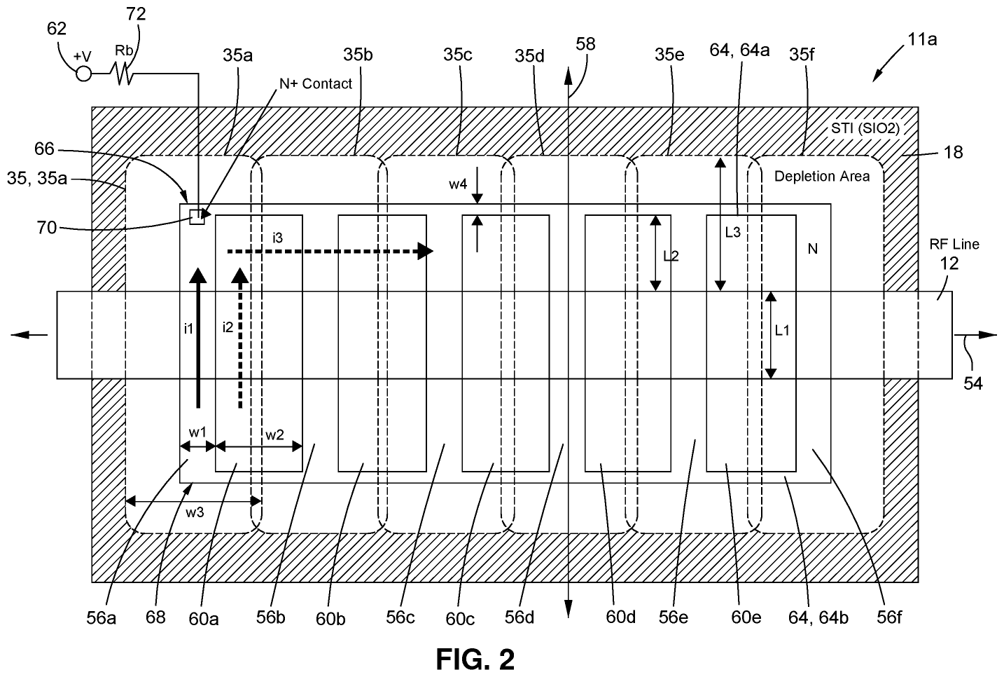

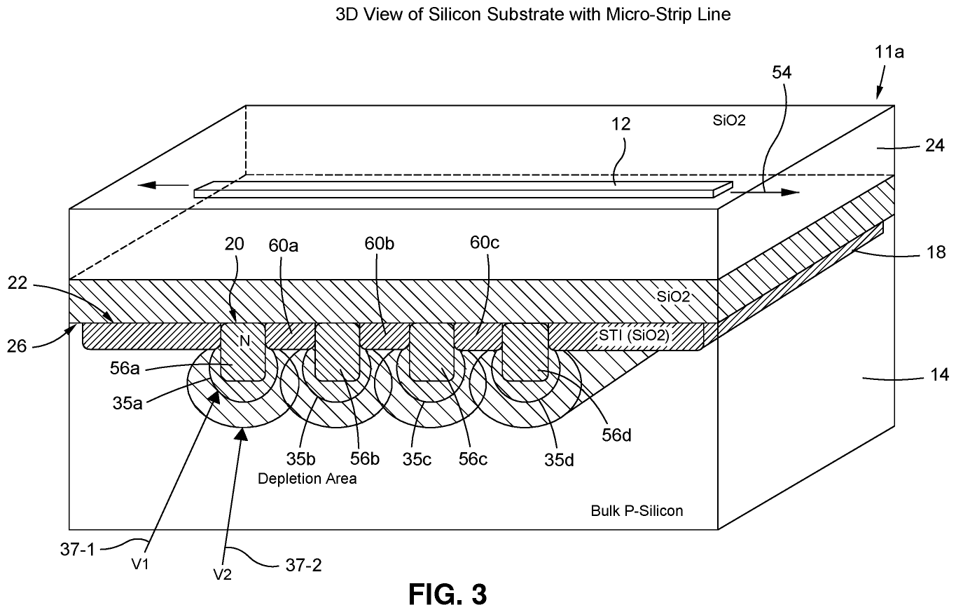

With reference to FIGS. 2 and 3, a first embodiment of a semiconductor integrated circuit transmission line structure 11a includes the semiconductor bulk substrate 14, which may be P-doped silicon. The semiconductor bulk substrate 14 may also be referred to as a first doped semiconductor substrate. As discussed above, the RF transmission line 12 is disposed on the inter-layer dielectric 24. Furthermore, the RF transmission line 12 extends along a longitudinal transmission line axis 54 and has a proscribed thickness and width (L1).

Various embodiments of the disclosure contemplate one or more lateral N-type strips 56, also referred to as second doped semiconductor strips. FIG. 2 depicts a first lateral N-type strip 56a, a second lateral N-type strip 56b, a third lateral N-type strip 56c, a fourth lateral N-type strip 56d, a fifth lateral N-type strip 56e, and a sixth lateral N-type strip 56f. The total number of lateral N-type strips 56 may be varied, and FIG. 3 illustrates another example with four (first lateral N-type strip 56a, second lateral N-type strip 56b, third lateral N-type strip 56c, and fourth lateral N-type strip 56d. In this regard, the perspective view shown in FIG. 3 is not intended as a representation of the exact same transmission line structure 11a shown in the top plan view of FIG. 2.

The lateral N-type strips 56 have an elongate structure extending along a longitudinal axis 58 that is transverse to the longitudinal transmission line axis 54, and has a predetermined width (w1), length, and thickness. More particularly, the lateral N-type strips 56 are defined in the semiconductor bulk substrate 14 and are in a spaced relation to each other along the longitudinal transmission line axis 54 by a proscribed offset distance (w2). The shallow trench isolation (STI) structure 18 is laterally adjacent to the N-type strips 56. In the first embodiment of the semiconductor integrated circuit transmission line structure 11a, a part of the STI structure 18 surrounds the lateral N-type strips 56 and isolates the same from the remainder of the semiconductor bulk substrate 14. Additionally, in between each of the individual lateral N-type strips 56, there may be an STI island structure 60. Specifically, between the first lateral N-type strip 56a and the second lateral N-type strip 56b, there may be a first STI island structure 60a, and between the second lateral N-type strip 56b and the third lateral N-type strip 56c, there may be a second STI island structure 60b. Similarly, between the third lateral N-type strip 56c and the fourth lateral N-type strip 56d, there may be a third STI island structure 60c. As illustrated in FIG. 3, between the fourth lateral N-type strip 56d and the fifth lateral N-type strip 56e there may be a fourth STI island structure 60d, and between the fifth lateral N-type strip 56e and the sixth lateral N-type strip 56f there may be a fifth STI island structure 60d. Each of the STI island structures 60, like the surrounding STI structure 18, is understood to be SiO₂, and may be fabricated in accordance with conventional STI techniques.

In general, the top surfaces 22 of the STI structures 18, 60 are understood to be co-planar with the top surfaces of the lateral N-type strip 56, each of which face and abut against the bottom surface 26 of the inter-layer dielectric 24. The lateral N-type strips 56, however, may have a thickness greater than that of the STI island structure 60, and may therefore extend to a greater depth into the semiconductor bulk substrate 14.

The width (w1) of the lateral N-type strips 56 may be varied, but according to an embodiment of the disclosure, may be less than a twentieth of the wavelength A of the E-field and H-field through the semiconductor bulk substrate 14, e.g., Λ/20. As discussed above, a depletion region 35 is defined at the P-N junction between the lateral N-type strips 56 and the P-type semiconductor bulk substrate 14. Thus, there are understood to be depletion regions 35a-35f corresponding to each of the lateral N-type strips 56a-56f and surround the same by a generally uniform distance. The spacing between each of the lateral N-type strips 56 (w2) in one embodiment is such that the there is a slight overlap in the depletion regions 35 of adjacent ones of the lateral N-type strips 56. For example, the first lateral N-type strip 56a defines a first depletion region 35a, which slightly overlaps with a second depletion region 35b defined by the second lateral N-type strip 56b, and so on. By selecting the appropriate dimensional parameters for w1 and w2, RF current induced into the semiconductor bulk substrate 14 from the RF transmission line 12 as a consequence of the propagating signal i3 may be significantly reduced in the transverse direction i2 in the depletion region 35.

The cross-sectional view of FIG. 3 best illustrates the depletion regions 35 relative to components of the semiconductor integrated circuit transmission line structure 11 and is shown extending into the semiconductor bulk substrate 14. The depletion region 35 is defined in both the P-type semiconductor bulk substrate 14 as well as the N-type material of the strips 56. As is well understood, in simplified form, the distance of the negative charge region xₙ, is given by:

$$\sqrt{\frac{2 {ϵ}_{s}}{q} \frac{{N}_{a}}{{N}_{d}} \frac{1}{{N}_{a} + {N}_{d}} ( Δ V )} ,$$

and the positive charge region xₚ is given by:

$$\sqrt{\frac{2 {ϵ}_{s}}{q} \frac{{N}_{d}}{{N}_{a}} \frac{1}{{N}_{a} + {N}_{d}} ( Δ V )} ,$$

where Nₐ is the number of acceptor atoms, N_{d} is the number of donor atoms, q is the electron charge, ΔV is the voltage and ∈ₛ is the permittivity of the material. In a typical manufacture of the semiconductor integrated circuit 1, however, the doping level in the N-well is substantially higher, and in many cases one to three orders of magnitude than that of the P-type semiconductor bulk substrate 14. Accordingly, most of the depletion region is defined in the semiconductor bulk substrate 14. Furthermore, the depletion region 35 in areas proximal to the STI structure

In the first embodiment of the semiconductor integrated circuit transmission line structure 11a, the individual lateral N-type strips 56a may be centered on the longitudinal transmission line axis 54, with an extension length L2 extending beyond the RF transmission line 12 by an equal distance. Thus, the length of the lateral N-type strips 56 may be defined by the width L1 of the RF transmission line 12, plus double the extension length L2, or L1+(2*L2). Various embodiments contemplate such length as being less than Λ/10 but is sufficiently long to cover a wide electric field area in areas adjacent to the RF transmission line 12. This is understood to significantly reduce loss in the transverse direction i1 in the lateral N-type strips 56.

Generally, in several embodiments of the semiconductor integrated circuit transmission line structure 11, the lateral N-type strips 56 may be connectible to a positive voltage source 62. In the first embodiment 11a, the lateral N-type strips 56a are connected to each other with longitudinal N-type strips 64. More particularly, each of the lateral N-type strips 56 are defined by a first end 66 and an opposed second end 68. A first longitudinal N-type strip 64a is positioned toward the first ends 66 of each of the lateral N-type strips 56 and establishing structural and electrical contiguity therewith. Additionally, a second longitudinal N-type strip 64b is positioned toward the second ends 68 of each of the lateral N-type strips 56, with structural and electrical contiguity between each being established. The width w4 of the longitudinal N-type strips 64 may be less than or equal to the width w1 of the lateral N-type strips 56. The longitudinal N-type strips 64 may be more generally referred to as longitudinal second doped strips, but regardless of the specific semiconductor configuration, is understood to have the same semiconductor material parameters as the lateral second doped strips or lateral N-type strips 56.

With a unitary structure of the lateral and longitudinal N-type strips 56, 64, only a single contact 70 may be used for the connection to the voltage source 62. Other embodiments contemplate different voltage source connection modalities, as will be described in further detail below. The lateral and longitudinal N-type strips 56, 64 are connected to the voltage source 62 over a resistor 72 which, in an exemplary embodiment, may have a resistance value of greater than 10 kOhm. Referring to the cross-sectional view of FIG. 3 and the equations for the distance of the positive charge region xₚ and the negative charge region xₙ, the application of the positive voltage to the N-type strips 56, 64 is understood to widen the depletion region 35 in the transverse direction as well as the vertical direction. The depicted boundary 37-1 is understood to correspond to the depletion region 35 with the voltage source 62 deactivated, while the boundary 37-2 is understood to correspond to the depletion region 35 with the voltage source 62 activated. The expanded depletion region 35 may further reduce overall loss.

The embodiments of the present disclosure utilize a P-type silicon substrate and a N-type strip, though this is by way of example only and not of limitation. In some semiconductor foundries, an N-type silicon substrate may be utilized, meaning that the first-doped substrate is an N-type semiconductor. In such case, the second-doped strip is a P-type semiconductor. With such embodiments, the voltage source 62 is understood to provide a negative voltage.

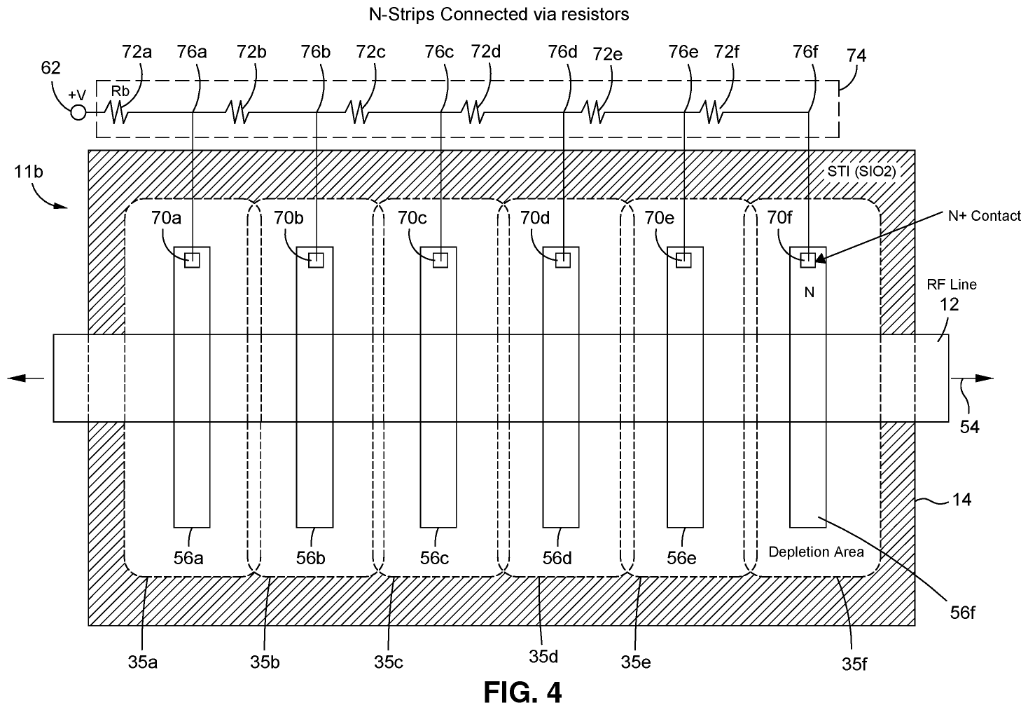

FIG. 4 illustrates a second embodiment of the semiconductor integrated circuit transmission line structure 11b, which includes the semiconductor bulk substrate 14 and the RF transmission line 12 disposed on the inter-layer dielectric 24 that are the same as the first embodiment 11a. Again, the RF transmission line 12 extends along a longitudinal transmission line axis 54. Similar lateral N-type strips 56 underlie the RF transmission line 12 and extend in a transverse relation to the longitudinal transmission line axis 54. The depicted embodiment of the semiconductor integrated circuit transmission line structure shows the first lateral N-type strip 56a, the second lateral N-type strip 56b, the third lateral N-type strip 56c, the fourth lateral N-type strip 56d, the fifth lateral N-type strip 56e, and the sixth lateral N-type strip 56f. The lateral N-type strips 56 are defined in the semiconductor bulk substrate 14 and are in a spaced relation to each other along the longitudinal transmission line axis 54. The shallow trench isolation (STI) structure 18 is laterally adjacent to the N-type strips 56.

Depletion regions 35 are defined at the P-N junction between the lateral N-type strips 56 and the P-type semiconductor bulk substrate 14. Thus, there are understood to be depletion regions 35a-35f corresponding to each of the lateral N-type strips 56a-56f and surround the same by a generally uniform distance. The spacing between each of the lateral N-type strips is such that the there is a slight overlap in the depletion regions 35 of adjacent ones of the lateral N-type strips 56.

Each of the lateral N-type strips 56 in the second embodiment of the semiconductor integrated circuit transmission line structure 11b are independent, in that there are no connective semiconductor elements (e.g., N-well components) structurally linking any two together as was otherwise the case in the first embodiment 11a, where longitudinal N-type strips 64 at opposed first and second ends 66, 68 of the lateral N-type strips 56 defined a unitary construction. Rather, the lateral N-type strips 56 each include a corresponding contact 70; the first lateral N-type strip 56a has a first contact 70a, the second lateral N-type strip 56b has a second contact 70b, the third lateral N-type strip 56c has a third contact 70c, the fourth lateral N-type strip 56d has a fourth contact 70d, the fifth lateral N-type strip 56e has a fifth contact 70e, and the sixth lateral N-type strip 56f has a sixth contact 70f.

The contacts 70 may each be connectible to successive nodes of a series network 74 of resistors. In an exemplary embodiment, the series network 74 includes a first resistor 72a, a second resistor 72b, a third resistor 72c, a fourth resistor 72d, a fifth resistor 72e, and a sixth resistor 72f, each of which are successively connected in series. The first contact 70a may be connected to a first junction 76a between the first resistor 72a and the second resistor 72b. The second contact 70b may be connected to a second junction 76b between the second resistor 72b and the third resistor 72c. The third contact 70c may be connected to a third junction 76c between the third resistor 72c and the fourth resistor 72d. The fourth contact 70d may be connected to a fourth junction 76d between the fourth resistor 72d and the fifth resistor 72e. The fifth contact 70e may be connected to a fifth junction 76e between the fifth resistor 72e and the sixth resistor 72f. Lastly, the sixth contact 70f may be connected to a sixth junction 76f after the sixth resistor 72f Each of the resistors 72 may have a large value greater than 1 kOhm, which is envisioned to significantly reduce current in the longitudinal direction of the RF transmission line 12.

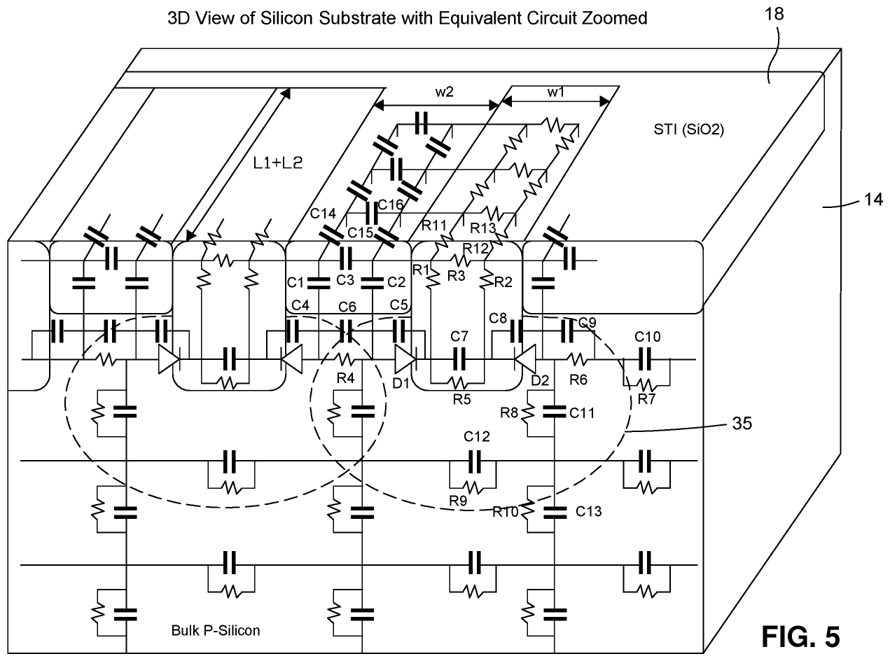

The cross-sectional view of FIG. 5 depicts the second embodiment of the semiconductor integrated circuit transmission line structure 11b, with equivalent circuit components that correspond to the various components thereof discussed above. The resistors R1 and R2 represent losses in the lateral N-type strip 56 that are associated with the electrical field (E-field) in the vertical direction. Furthermore, resistors R5, R3, and R13 represent losses in the lateral N-type strip 56 that are associated with the magnetic field (H-field) in the transverse direction. Along these lines, resistors R11 and R12 represent losses in the lateral N-type strip 56 that are associated with the electrical field (E-field) in the transverse direction. Next, capacitor C7 represents the capacitance that is associated with the free charge carriers in the lateral N-type strip 56.

The diodes D1 and D2 are understood to be those that correspond to the P-N junction in the longitudinal direction (e.g., along the longitudinal transmission line axis 54). It is understood that there are similar diodes corresponding to the vertical and transverse directions but are not shown in FIG. 5. Capacitances are also associated with these P-N junctions, as represented by the capacitors C4, C5, and C8. In further detail, the capacitors C6 and C9 are the capacitances associated with the partial depletion area in the vicinity of the STI plane in the longitudinal direction. Such partial depletion area also has associated resistances, including the resistor R4 and R6. Furthermore, the resistor R8 and the capacitor C11 correspond to resistances and capacitances that are associated with the fully depleted region in the vertical direction, and the resistor R9 and the capacitor C12 correspond to resistances and capacitances that are associated with the fully depleted region in the longitudinal direction. The resistor R7 and the capacitor C10 correspond to the resistance and capacitance associated with the P-type semiconductor bulk substrate 14 in the longitudinal direction while the resistor R10 and the capacitor C13 correspond to the resistance and capacitance associated with the same P-type semiconductor bulk substrate 14 in the vertical direction. The capacitors C1, C2, C3, C14, C15, and C16 are the capacitances associated with the STI structure 18 in the longitudinal direction, the vertical direction, and the transverse direction.

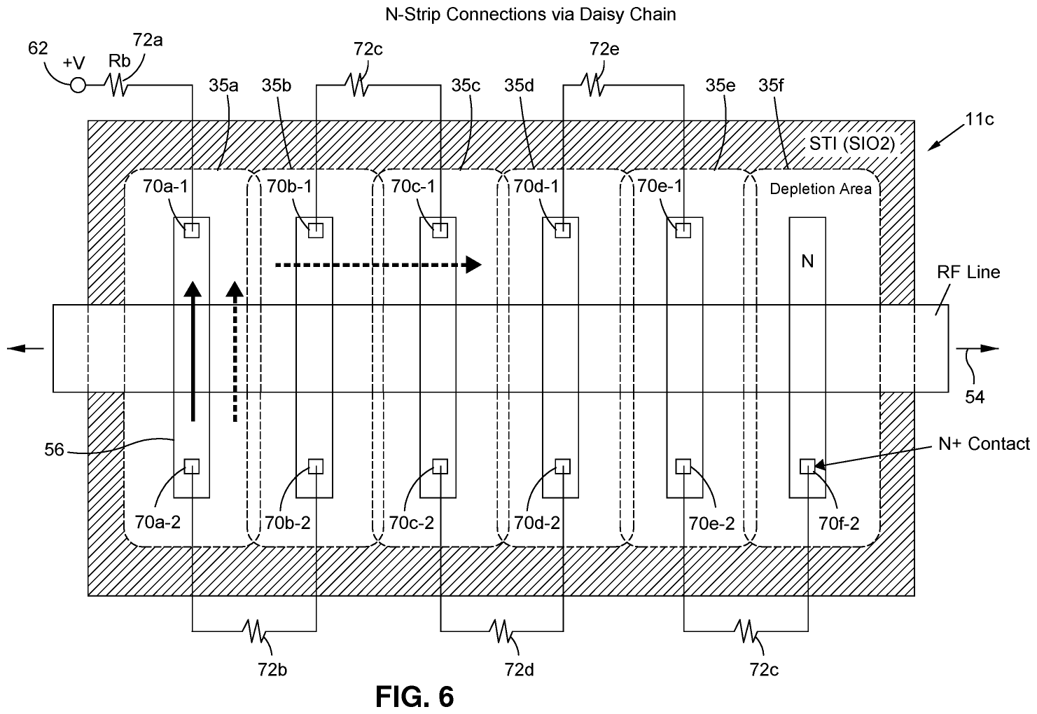

FIG. 6 illustrates a third embodiment of the semiconductor integrated circuit transmission line structure 11c, which again includes the same semiconductor bulk substrate 14 and the RF transmission line 12 disposed on the inter-layer dielectric 24 as the first and second embodiment 11a, 11b. The RF transmission line 12 extends along a longitudinal transmission line axis 54, and lateral N-type strips 56 underlie the RF transmission line 12 and extend in a transverse relation to the longitudinal transmission line axis 54. The depicted embodiment of the semiconductor integrated circuit transmission line structure shows the first lateral N-type strip 56a, the second lateral N-type strip 56b, the third lateral N-type strip 56c, the fourth lateral N-type strip 56d, the fifth lateral N-type strip 56e, and the sixth lateral N-type strip 56f. The lateral N-type strips 56 are defined in the semiconductor bulk substrate 14 and are in a spaced relation to each other along the longitudinal transmission line axis 54. The shallow trench isolation (STI) structure 18 is laterally adjacent to the N-type strips 56.

Depletion regions 35 are defined at the P-N junction between the lateral N-type strips 56 and the P-type semiconductor bulk substrate 14. Thus, there are understood to be depletion regions 35a-35f corresponding to each of the lateral N-type strips 56a-56f and surround the same by a generally uniform distance. The spacing between each of the lateral N-type strips is such that the there is a slight overlap in the depletion regions 35 of adjacent ones of the lateral N-type strips 56.

Each of the lateral N-type strips 56 in the third embodiment of the semiconductor integrated circuit transmission line structure 11b are independent, in that there are no connective semiconductor elements structurally linking any two together. Generally, the lateral N-type strips 56 are sequentially connected over successive resistors in series in a daisy chain configuration. The lateral N-type strips 56 each have first end contacts 70-1 and second end contacts 70-2 corresponding to and disposed at the first ends 66 and the second ends 68 thereof. The first lateral N-type strip 56a incorporates a first end contact 70a-1 and a second end contact 70a-2, the second lateral N-type strip 56b incorporates a first end contact 70b-1 and a second end contact 70b-2. Along these lines, the third lateral N-type strip 56c incorporates a first end contact 70c-1 and a second end contact 70c-2, the fourth lateral N-type strip 56d incorporates a first end contact 70d-1 and a second end contact 70d-2, and a fifth lateral N-type strip 56e incorporates a first end contact 70e-1 and a second end contact 70e-2. Because the sixth lateral N-type strip 56f is the terminal end of the daisy chain, there is only a second end contact 70f-2.

There are resistors between each contact 70 of the lateral N-type strips 56. In further detail, the first end contact 70a-1 of the first lateral N-type strip 56a is connected to the voltage source 62 over a resistor Rb 72a. Next, the first lateral N-type strip 56a is connected to the second lateral N-type strip 56b via the second end contacts 70a-2 and 70b-2 over a second resistor 72b. The second lateral N-type strip 56b is then connected to the third lateral N-type strip 56c via the first end contacts 70b-1 and 70c-1 over a third resistor 72c. Thereafter, the third lateral N-type strip 56c is connected to the fourth lateral N-type strip 56d via the second end contacts 70c-2 and 70d-2 over a fourth resistor 72d, and the fourth lateral N-type strip 56d is connected to the fifth lateral N-type strip 56e via the first end contacts 70d-1 and 70e-1 over the fifth resistor 72e. Lastly, the fifth lateral N-type strip 56e is connected to the sixth lateral N-type strip 56f via the second end contacts 70e-2 and 70f-2 over the sixth resistor 72f. According to the one embodiment, the resistors 72 may have a large value of greater than 1 kOhm.

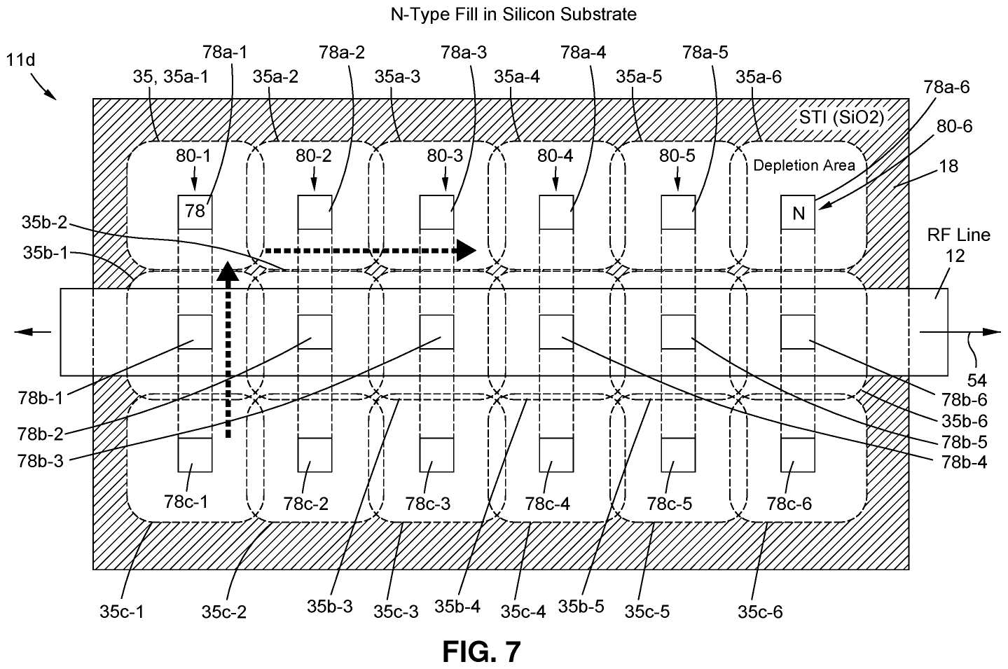

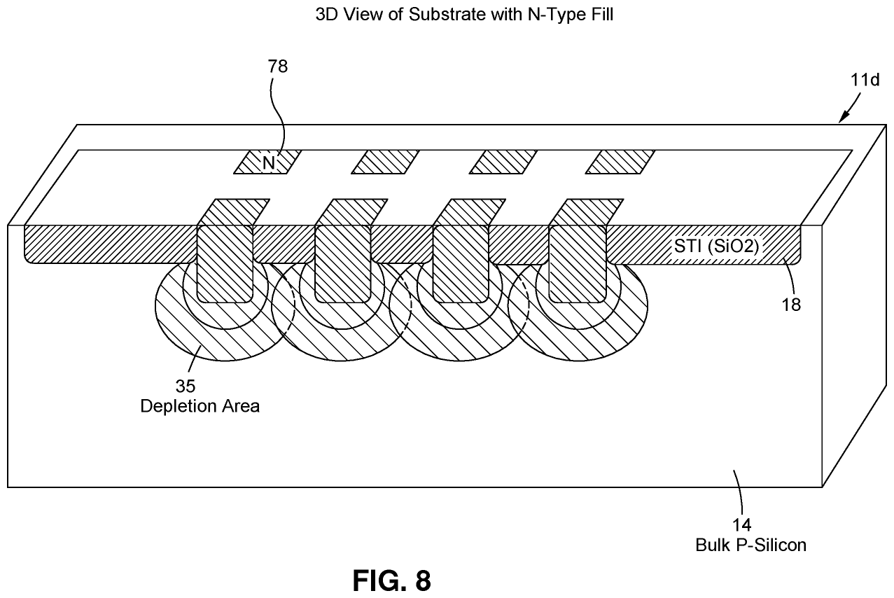

With reference to FIGS. 7 and 8, a fourth embodiment of the semiconductor integrated circuit transmission line structure 11d includes the same semiconductor bulk substrate 14 and the RF transmission line 12 disposed on the inter-layer dielectric 24. The RF transmission line 12 extends along the longitudinal transmission line axis 54. These aspects are understood to be the same as the first, second, and third embodiments 11a-11c. The fourth embodiment contemplates multiple N-type fills 78 that are arranged in a proscribed pattern. As was the case with the previously described embodiments, the N-type fill 78 may be more generally referred to as a second-doped semiconductor fill, as distinguished from the first-doped or P-type semiconductor bulk substrate 14.

One possible spaced arrangement is as one or more sets of multiple, e.g., three N-type fills 78 that are transverse to the longitudinal transmission line axis 54. For instance, a first set 80-1 may include a first N-type fill 78a-1, a second N-type fill 78b-1, and a third N-type fill 78c-1. A second set 80-2 may include a first N-type fill 78a-2, a second N-type fill 78b-2, and a third N-type fill 78c-2. A third set 80-3 may include a first N-type fill 78a-3, a second N-type fill 78b-3, and a third N-type fill 78c-3. A fourth set 80-4 may include a first N-type fill 78a-4, a second N-type fill 78b-4, and a third N-type fill 78c-4. A fifth set 80-5 may include a first N-type fill 78a-5, a second N-type fill 78b-5, and a third N-type fill 78c-5. Lastly, a sixth set 80-6 may include a first N-type fill 78a-6, a second N-type fill 78b-6, and a third N-type fill 78c-6. The shallow trench isolation (STI) structure 18 is laterally adjacent to the N-type fills 78.

Depletion regions 35 are defined at the P-N junction between the lateral N-type strips 56 and the P-type semiconductor bulk substrate 14. Thus, there are understood to be depletion regions 35a-1 to 35c-6 corresponding to each of the N-type fills 78a-1 to 78c-6 and surround the same by a generally uniform distance. The spacing between each of the N-type fills 78 is such that the there is a slight overlap in the depletion regions 35 of adjacent ones of the N-type fills 78. The size of each of the N-type fills 78 may be less than Λ/20, with resultant reduced losses through such elements.

In the fourth embodiment of the semiconductor integrated circuit transmission line structure 11d, the N-type fills 78 are not connected to any voltage source unlike the previously described embodiments, and is understood to be suitable for implementation with a P-type semiconductor bulk substrate 14 that has a resistivity of greater than or equal to 10 Ohm*cm. The depletion region 35 is understood to have a depth of greater than 1 μm despite lacking an externally applied voltage to the N-doped regions. This embodiment also contemplates the reduction of losses associated with transverse RF currents that otherwise may be induced in the lateral N-type strips 56. Additionally, longitudinal induced currents in the semiconductor bulk substrate 14 are significantly reduced, which result in an overall reduction of losses.

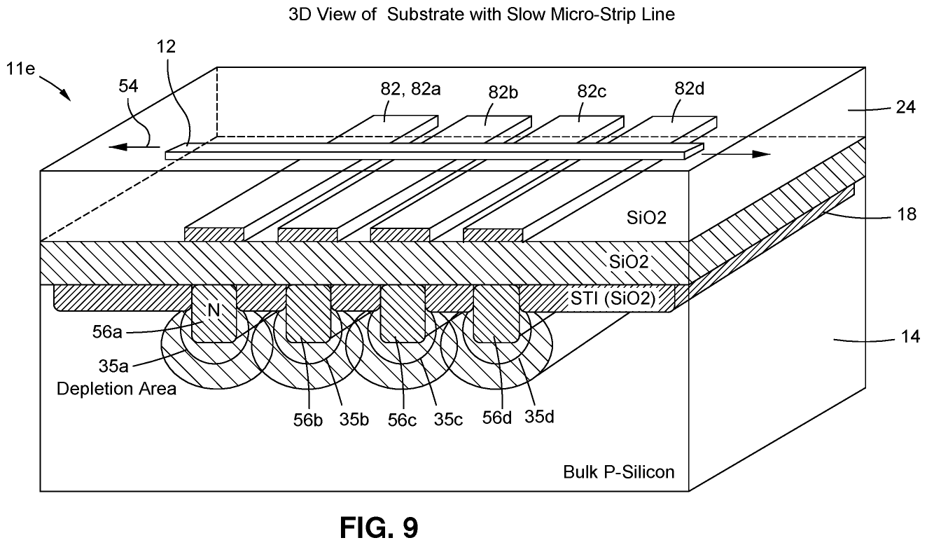

FIG. 9 illustrates a fifth embodiment of the semiconductor integrated circuit transmission line structure 11e, which includes the semiconductor bulk substrate 14 and the RF transmission line 12 disposed on the inter-layer dielectric 24 that are the same as the first embodiment 11a. The RF transmission line 12 extends along a longitudinal transmission line axis 54. The lateral N-type strips 56 underlie the RF transmission line 12 and extend in a transverse relation to the longitudinal transmission line axis 54. The depicted embodiment of the semiconductor integrated circuit transmission line structure 11e shows the first lateral N-type strip 56a, the second lateral N-type strip 56b, the third lateral N-type strip 56c, and the fourth lateral N-type strip 56d. The lateral N-type strips 56 are defined in the semiconductor bulk substrate 14 and are in a spaced relation to each other along the longitudinal transmission line axis 54. The shallow trench isolation (STI) structure 18 is laterally adjacent to the N-type strips 56.

In addition to the foregoing features that are common with the first embodiment, slow-wave microstrip lines 82 are disposed underneath the RF transmission line 12 in a transverse relation to the longitudinal transmission line axis 54. The slow-wave microstrip lines 82, which may be referenced more generally as metal strips, are located within the inter-layer dielectric 24 and generally overlap the lateral N-type strips 56. Thus, a first slow-wave microstrip line 82a may overlap the first lateral N-type strip 56a, a second slow-wave microstrip line 82b may overlap the second lateral N-type strip 56b, a third slow-wave microstrip line 82c may overlap the third lateral N-type strip 56c, a fourth slow-wave microstrip line 82d may overlap the fourth lateral N-type strip 56d, and so on. In alternative embodiments, a single slow-wave microstrip line 82 may cover or overlap multiple lateral N-type strips 56. These slow-wave microstrip lines 82 are envisioned to block the H-field and E-field components emitted from the RF transmission line 12 from reaching the lateral N-type strips 56, and RF current may not be flowing thereto. As a result, an overall reduction of losses from the signal propagating through the RF transmission line 12 may be possible.

Nevertheless, depletion regions 35 are still defined at the P-N junction between the lateral N-type strips 56 and the P-type semiconductor bulk substrate 14. Thus, there are understood to be depletion regions 35a-35d corresponding to each of the lateral N-type strips 56a-56d and surround the same by a generally uniform distance. The spacing between each of the lateral N-type strips is such that the there is a slight overlap in the depletion regions 35 of adjacent ones of the lateral N-type strips 56.

Although the described embodiments were specific to transmission lines, this is by way of example only and not of limitation. The same disclosed features may be utilized in the context of inductors, MoM (metal oxide metal) capacitors, transformers, coupled inductors, or any other type of passive device in which high Q and low insertion loss are desirable. In this regard, the transmission line may be referenced more broadly as an integrated circuit element that is likewise defined by a circuit element axis along which a signal through such integrated circuit element passes.

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A semiconductor integrated circuit transmission line structure, comprising:
a first dielectric layer;
a transmission line disposed on the first dielectric layer and extending along a transmission line axis;
a first doped semiconductor substrate;
one or more lateral second doped semiconductor strips defined in the first doped semiconductor substrate and each connectible to a voltage source, the lateral second doped semiconductor strips being transverse to the transmission line axis and spaced along the transmission line; and
a shallow trench isolation structure defined in the first doped semiconductor substrate and laterally adjacent to the lateral second doped semiconductor strips.

2. The semiconductor integrated circuit transmission line structure of claim 1, wherein depletion regions of increased resistance are defined from the lateral second doped semiconductor strips to areas of the first doped semiconductor substrate adjacent thereto with a voltage being applied to the lateral second doped semiconductor strips.

3. The semiconductor integrated circuit transmission line structure of claim 2, wherein the lateral second doped semiconductor strips are spaced for an overlapping relationship between the corresponding depletion regions defined thereby.

4. The semiconductor integrated circuit transmission line structure of claim 1, wherein each of the lateral second doped semiconductor strips is defined by a first end and an opposed second end.

5. The semiconductor integrated circuit transmission line structure of claim 4, further comprising longitudinal second doped semiconductor strips connecting respective ones of the first and second ends of each of the lateral second doped semiconductor strips.

6. The semiconductor integrated circuit transmission line structure of claim 5 further comprising a single voltage source contact connected to any one of the lateral or longitudinal second doped semiconductor strips.

7. The semiconductor integrated circuit transmission line structure of claim 5, wherein a width of the longitudinal second doped semiconductor strips is less than a width of the second doped semiconductor strips.

8. The semiconductor integrated circuit transmission line structure of claim 1, further comprising voltage source contacts connected to each of the lateral second doped semiconductor strips, and the voltage source contacts are each connectible to a successive node of a series network of resistors.

9. The semiconductor integrated circuit transmission line structure of claim 1, further comprising voltage source contacts connected to respective first and second ends of each of the lateral second doped semiconductor strips, one of the second doped semiconductor strips being interconnected to another one of the second doped semiconductor strip in a daisy-chained relationship.

10. The semiconductor integrated circuit transmission line structure of claim 1, further comprising one or more slow-wave micro-strip lines transverse to the transmission line axis and spaced along the transmission line.

11. The semiconductor integrated circuit transmission line structure of claim 10, wherein the slow-wave micro-strip lines overlap the second doped semiconductor strips.

12. The semiconductor integrated circuit transmission line structure of claim 11, wherein a given one of the slow-wave micro-strip lines overlap a plurality of second doped semiconductor strips.

13. The semiconductor integrated circuit transmission line structure of claim 1, wherein the first doped semiconductor substrate is a P-type semiconductor, and the lateral second doped semiconductor strips are an N-type semiconductor.

14. A semiconductor integrated circuit transmission line structure, comprising:
a first doped semiconductor substrate;
a transmission line extending along a transmission line axis;
one or more sets of second doped semiconductor fills, each of the second doped semiconductor fills in a given set being arranged in a spaced relation transverse to the transmission line axis, and each of the sets being spaced along the transmission line; and
a shallow trench isolation structure defined in the first doped semiconductor substrate and laterally adjacent to the lateral second doped semiconductor fills.

15. The semiconductor integrated circuit transmission line structure of claim 14, wherein depletion regions are defined from the second doped semiconductor fills to areas of the first doped semiconductor substrate adjacent thereto.

16. The semiconductor integrated circuit transmission line structure of claim 15, wherein the second doped semiconductor fills are spaced for an overlapping relationship between the corresponding depletion regions defined thereby.

17. The semiconductor integrated circuit transmission line structure of claim 14, wherein the first doped semiconductor substrate has a resistivity greater than or equal to 10 Ohm*cm.

18. A semiconductor die comprising:
a first doped semiconductor substrate;
an integrated circuit element disposed above the first doped semiconductor substrate and extending along a circuit element axis; and
a second doped semiconductor segment defined in the first doped semiconductor substrate, the second doped semiconductor segment being arranged in a transverse relationship to the circuit element axis, a depletion region being defined in areas of the first doped semiconductor substrate adjacent thereto that reduces power loss in signals through the integrated circuit element.

19. The semiconductor die of claim 18, wherein the second doped semiconductor segment includes a contact connectible to a voltage source, and application of the voltage source increasing the depletion region.

20. The semiconductor die of claim 18, further comprising a shallow trench isolation structure defined in the first doped semiconductor substrate and laterally adjacent to the lateral second doped semiconductor segment.
